(19) United States
(12) Patent Application Publication
(10) Pub. No.: US 2013/0330911 A1
(43) Pub. Date: Dec. 12, 2013

(54) METHOD OF SEMICONDUCTOR FILM STABILIZATION

(71) Applicants: Yi-Chiau HUANG, Fremont, CA (US); Yihwan KIM, San Jose, CA (US); Errol Antonio C. SANCHEZ, Tracy, CA (US)

(72) Inventors: Yi-Chiau HUANG, Fremont, CA (US); Yihwan KIM, San Jose, CA (US); Errol Antonio C. SANCHEZ, Tracy, CA (US)

(21) Appl. No.: 13/796,061

(22) Filed: Mar. 12, 2013

Related U.S. Application Data
(60) Provisional application No. 61/657,494, filed on Jun. 8, 2012.
(60) Provisional application No. 61/660,382, filed on Jun. 15, 2012.

(51) Int. Cl. H01L 21/02

(52) U.S. Cl. CPC H01L 21/02535; H01L 21/02532
USPC 438/478

(57) ABSTRACT

Embodiments of the invention generally relate to methods for forming silicon-germanium-tin alloy epitaxial layers, germanium-tin alloy epitaxial layers, and germanium epitaxial layers that may be doped with boron, phosphorus, arsenic, or other n-type or p-type dopants. The methods generally include positioning a substrate in a processing chamber. A germanium precursor gas is then introduced into the chamber concurrently with a stressor precursor gas, such as a tin precursor gas, to form an epitaxial layer. The flow of the germanium gas is then halted, and an etchant gas is introduced into the chamber. An etch back is then performed while in the presence of the stressor precursor gas used in the formation of the epitaxial film. The flow of the etchant gas is then stopped, and the cycle may then be repeated. In addition to or as an alternative to the etch back process, an annealing processing may be performed.

### CROSS-REFERENCE TO RELATED APPLICATIONS

This application claims benefit of U.S. Provisional Patent Application Ser. No. 61/657,494, filed Jun. 8, 2012, and U.S. Provisional Patent Application Ser. No. 61/660,382, filed Jun. 15, 2012. The aforementioned applications are herein incorporated by reference.

### BACKGROUND OF THE INVENTION

1. Field of the Invention

Technology described herein relates to the manufacture of semiconductor devices. More specifically, methods are described for forming epitaxial group IV semiconductor materials.

2. Description of the Related Art

Germanium was one of the first materials used for semiconductor applications such as CMOS transistors. Due to vast abundance of silicon compared to germanium, however, silicon has been the overwhelming semiconductor material of choice for CMOS manufacture. As device geometries decline according to Moore's Law, the size of transistor components poses challenges to engineers working to make devices that are smaller, faster, use less power, and generate less heat. For example, as the size of a transistor declines, the channel region of the transistor becomes smaller, and the electronic properties of the channel become less viable, with more resistivity and higher threshold voltages. Carrier mobility is increased in the silicon channel area by using silicon-germanium stressors embedded in the source/drain areas, as some manufacturers have done for the 45 nm node. For future nodes, however, still higher mobility devices are needed.

One attempted method of forming higher mobility devices includes forming silicon-germanium-tin alloy, germanium-tin alloy, or germanium epitaxial layers. To improve the quality of the deposited epitaxial layers, a cyclical deposition/treatment process, such as deposition/etch or deposition/anneal may be performed. In the example of deposition/etch, after the deposition of a certain amount of epitaxial material, a brief etch back is performed to remove deposited material from masked areas to facilitate deposition selectivity. In another cyclical process, after deposition, the flow of deposition gases may be halted for a period of time, for example, to perform an anneal, which may improve the crystallinity of the epitaxial layer and/or activate dopants. However, during the non-deposition treatment of the epitaxial layer, the composition of silicon, germanium, and tin can change due to migration. Additionally, other dopants within the epitaxial layer, such as group III or group V elements, may also migrate or outgas, thus degrading film quality. Moreover, in the beginning of deposition in each cycle, the incorporation of a group IV element, for example tin, can lag the incorporation of other group IV elements such as silicon and/or germanium and/or even group III and group IV dopants. These are the potential sources of film degradation and reduced film composition uniformity.

FIG. 1 illustrates a germanium-tin alloy layer 102 formed on a silicon substrate 104 having a germanium buffer layer 106 thereon. The germanium-tin alloy layer 104 was formed using a deposition/anneal process performed for four cycles. The deposition/anneal process, however, does not result in a germanium-tin alloy layer having a uniform tin profile. Rather, due to migration of the tin during the anneal process, which may be partially due to the elevated temperatures during the anneal process or the initial transient stage of deposition in which the incorporation of tin can be poor, the deposited film includes four periodic layers of non-uniform tin concentration. The periodic layers of non-uniform concentration are indicated by the three higher order peaks 102a, 102b, and 102c of the germanium-tin alloy layer 102. The non-uniform tin depth profile is an undesirable property which reduces film quality.

Therefore, there is a need in the art for a method for forming epitaxial layers having uniform composition profiles.

### SUMMARY OF THE INVENTION

Embodiments of the invention generally relate to methods for forming silicon-germanium-tin alloy epitaxial layers, germanium-tin alloy epitaxial layers, and germanium epitaxial layers that may be doped with boron, phosphorus, arsenic, or other n-type or p-type dopants. The methods generally include positioning a substrate in a processing chamber. A germanium precursor gas, and optionally a silicon precursor gas and a group III or group V gas, is then introduced into the chamber concurrently with an alloying precursor gas, such as a tin precursor gas, to form an epitaxial layer. The flow of the germanium gas is then halted, and an etchant gas is introduced into the chamber. An etch back is then performed while in the presence of the alloying precursor gas used in the formation of the epitaxial film. The flow of the etchant gas is then stopped, and the cycle may then be repeated. In addition to or as an alternative to the etch back process, an annealing processing may be performed in the presence of the tin precursor. When a group III or group V gas is utilized, the group III or group V gas may also be provided to the processing chamber during the etching and/or annealing.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 illustrates X-Ray diffraction data for a GeSn film grown on a silicon substrate having a germanium buffer layer thereon.

FIG. 2 is a flow diagram of a method of forming a germanium-tin alloy epitaxial layer according to one embodiment of the invention.

FIG. 3 illustrates X-ray diffraction data for a germanium-tin alloy epitaxial layer formed on silicon substrate having a germanium buffer layer thereon.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally relate to methods for forming silicon-germanium-tin alloy epitaxial layers, germanium-tin alloy epitaxial layers, and germanium epitaxial layers that may be doped with boron, phosphorus, arsenic, or other n-type or p-type dopants. The methods generally include positioning a substrate in a processing chamber. A germanium precursor gas, and optionally a silicon precursor gas and a group III or group V gas, is then introduced into the chamber concurrently with an alloying precursor gas, such as a tin precursor gas, to form an epitaxial layer. The flow of the germanium gas is then halted, and an etchant gas is introduced into the chamber. An etch back is then performed while in the presence of the alloying precursor gas used in the formation of the epitaxial film. The flow of the etchant gas is then stopped, and the cycle may then be repeated. In addition to or as an alternative to the etch back process, an annealing processing may be performed in the presence of the tin precursor. When a group III or group V gas is utilized, the group III or group V gas may also be provided to the processing chamber during the etching and/or annealing.

In some embodiments of the invention, tin may be alloyed with germanium and/or silicon to form a silicon-germanium-tin alloy epitaxial layer or a germanium-tin alloy epitaxial layer. The alloying of tin with silicon and/or germanium increases the compressive stress/strain of the alloyed film, particularly when deposited on a germanium buffer layer. Additionally, the alloying of tin with germanium and/or silicon reduces the bandgap of the silicon or germanium and brings the “gamma valley” in the conduction band closer than the “L valley” to the valence band top. The carriers in the gamma valley have higher mobility than the carrier in the L valley due to the structure of the bandgap. Tin alloying above a certain point, for example about seven percent in germanium, facilitates high carrier mobility due to changes in the bandgap of the germanium which allow carriers of higher mobility to dominate in the conduction of electricity.

Embodiments of the invention may be practiced in a Centura® RP EPi chamber available from Applied Materials, Inc. in Santa Clara, Calif. It is contemplated, however, that other equipment, including equipment available from other manufacturers, may be utilized to practice embodiments of the invention.

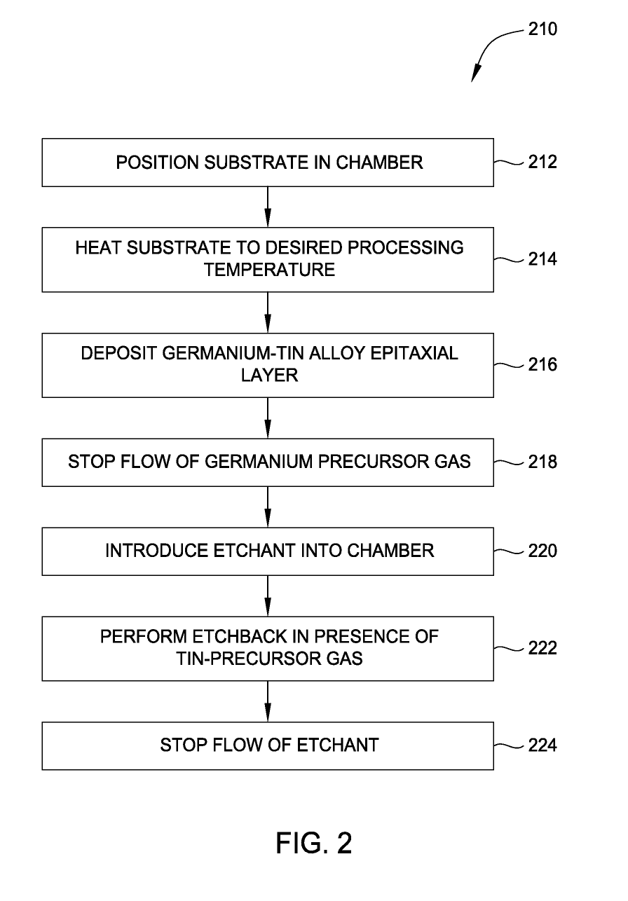

FIG. 2 is a flow diagram 210 of a method of forming a germanium-tin alloy epitaxial layer according to one embodiment of the invention. The flow diagram 210 begins at operation 212, in which a substrate, such as a 200 millimeter or a 300 millimeter silicon substrate is positioned within a process chamber. The silicon substrate may have a germanium buffer layer formed on a surface thereof. It is contemplated that the substrate may be any type of substrate, including semiconductor substrates. In one example, a silicon substrate on which a transistor structure is to be formed may be used. The substrate may have dielectric areas formed on a surface thereof.

In operation 214, the substrate is elevated to a desired processing temperature such as about 150° C. to about 500° C., for example between about 200° C. and about 400° C. In operation 216, a germanium-tin alloy epitaxial layer is formed on the substrate, for example, in a thermal chemical vapor deposition (CVD) process. The germanium-tin alloy epitaxial layer is formed on the substrate by introducing a germanium precursor gas and a tin precursor gas into the chamber. A carrier gas may optionally be introduced into the chamber as well. It is contemplated that the germanium precursor gas and the tin precursor gas may be thermally or chemically decomposed onto the substrate to form the germanium-tin alloy epitaxial layer.

Suitable germainum precursors include germanium hydrides such as germane (GeH₄), digermane (Ge₂H₆), or higher hydrides (GeₓH₂ₓ₊₂), or a combination thereof. The germainum precursor may be mixed with a carrier gas, which may be a non-reactive gas such as nitrogen gas, hydrogen gas, or a noble gas such as helium or argon, or a combination thereof. The ratio of germanium precursor volumetric flow rate to carrier gas volumetric flow rate may be used to control gas flow velocity through the chamber. The ratio may be any proportion from about 1% to about 99%, depending on the flow velocity desired. In some embodiments, a relatively high velocity may improve uniformity of the deposited layer. Pressure in the processing chamber is maintained between about 5 Torr and about 200 Torr, such as between about 20 Torr and about 80 Torr, for example about 40 Torr.

A tin precursor gas is introduced into the chamber concurrently with the germanium precursor gas to deposit a germanium-tin alloy epitaxial layer on the surface of the substrate. The tin precursor gas may include a tin halide gas. For example the dopant gas may be SnCl₄, SnCl₂, or an organometallic chloride having the formula RₓMCl_{y}, where R is methyl or t-butyl, x is 1 or 2, M is Sn, and y is 2 or 3. The tin precursor gas is provided to the processing chamber at a flow rate between about 0.1 sccm and about 300 sccm, such as between about 50 sccm and about 100 sccm, for example about 5 sccm. The tin precursor gas may also be mixed with a carrier gas to achieve a desired space velocity and/or mixing performance in the processing chamber. The tin precursor gas may be sourced from a solid source of crystals sublimed into a flowing carrier gas stream such as N₂, H₂, Ar, or He, or the tin precursor gas may be generated by passing a halogen gas, optionally with one of the above carrier gases, over a solid metal in a contacting chamber to perform the reaction M+2Cl₂→MCl₄, where M is Sn. The contacting chamber may be adjacent to the processing chamber, coupled thereto by a conduit which is preferably short to reduce the possibility of metal halide particles depositing in the conduit.

The germanium-tin alloy epitaxial layer may be deposited to a thickness between about 100 Å and about 800 Å. In one example, the concentration of tin atoms in a germanium matrix may be between about one percent and about 12 percent, such as between about seven percent and about nine percent.

The tin precursor gas and the germanium precursor gas are usually provided to the processing chamber through different pathways. The germanium precursor gas is provided through a first pathway, and the tin precursor gas is provided through a second pathway. The two pathways are generally different and kept separate up to the point of entry into the processing chamber. In one embodiment, both streams enter through a side wall of the chamber proximate an edge of the substrate support, travel across the substrate support from one side to an opposite side thereof and into an exhaust system. The substrate support may rotate during formation of the germanium-tin alloy epitaxial film to improve uniformity. The first pathway generally communicates with a first entry point into the processing chamber, which may comprise one or more openings in a wall of the chamber or a gas distributor, such as a showerhead, coupled to a wall of the chamber. The one or more openings may be proximate an edge of the substrate support or may be portals in a dual or multi path gas distributor. The second pathway likewise communicates with a second entry point similar to the first entry point. The first and second entry points are disposed such that the two streams mix and provide a deposition or layer growth mixture in a region above the substrate support. Use of a gas distributor may reduce or eliminate the need to rotate the substrate during processing in some embodiments.

In operation 218, the flow of the germanium precursor gas is halted. Subsequently, in operation 220, an etchant is introduced into the processing chamber. The etchant gas may be, for example, Cl₂ or HCl. In operation 222 an etch back of the deposited material is performed in the presence of the tin precursor gas. It is contemplated that the flow of the tin precursor gas may be continuous throughout the deposition and etch, or the flow of the tin precursor gas may be stopped after the deposition process and then resumed for the etch back process.

During the etch back process, the tin precursor gas continues to be introduced into the processing chamber, for example, at substantially the same flow rate as during the deposition process described with respect to operation 216. The presence of the tin precursor gas within the chamber during the etch back process reduces the migration of the tin within the germanium-tin alloy epitaxial film, resulting in a film of uniform tin composition. It is believed that the reduced migration of the tin can at least be partly contributed to the partial pressure of tin in the process chamber atmosphere. Because the migration of the tin is reduced, each deposition/etch of the cyclical process can be repeatedly performed to form a germanium-tin alloy epitaxial layer of uniform tin composition. In operation 224, the flow of etching gas is halted. The deposition/etch process may then be repeated.

FIG. 2 illustrates one embodiment of a cyclical deposition process; however, additional embodiments are also contemplated. In another embodiment, it is contemplated that the germanium-tin alloy epitaxial layer may also include silicon. In such an embodiment, a silicon-germanium-tin epitaxial layer may be formed. Suitable silicon precursors include silicon hydrides such as silane and disilane. In another embodiment, it is contemplated that lead may be utilized rather than tin. In yet another embodiment, it is contemplated that a group III or group V dopant may be provided to the chamber concurrently with the germanium and the tin in order to form a doped germanium-tin alloy or doped silicon-germanium-tin alloy. Suitable dopants include n-type and p-type dopants such as boron, arsenic and phosphorus. In one example, diborane may be introduced into the chamber during deposition to dope the epitaxial film with boron. In such an embodiment, both a boron precursor and a tin precursor may be provided to the process chamber during the non-deposition phase of the cyclical deposition process (e.g., etch back or annealing), to reduce the out gassing and/or migration of tin and the dopant. It is contemplated that more than one dopant may be incorporated into the epitaxial film.

In yet another embodiment, it is contemplated that a germanium epitaxial layer which includes a group III or group V dopant may be deposited without the incorporation of tin. In such an embodiment, the presence of the dopant in the chamber atmosphere during processing reduces out gassing and migration of the group III or group V dopant. In another embodiment, it is contemplated that the etch process may be replaced with an annealing process which may occur in an annealing gas atmosphere. For example, a boron-doped germanium epitaxial film may be formed, and then the film may be annealed to activate the dopant. In such an embodiment, the dopant gas is provided to the processing chamber during both the deposition process and the annealing process. Because the dopant gas is provided to the chamber during the annealing process, out gassing and migration of the dopant within the germanium epitaxial layer is reduced.

In yet another embodiment, it is contemplated that the tin precursor gas or dopant gas used during the formation of the epitaxial layer and the tin precursor gas or dopant gas used during the etch process may be different gases. In such an embodiment, the two different gases generally include the same dopants species (e.g., tin). Thus, it is not necessary that the same gas be present in the chamber atmosphere during non-deposition processes; rather the presence of the same species is generally sufficient to reduce undesired migration and out gassing.

In yet another embodiment, it is contemplated that the tin precursor gas may be optionally introduced to the processing chamber prior to operation 216 to pre-condition the substrate and/or the processing chamber. Preconditioning of the substrate and/or the processing chamber mitigates the “lag” of incorporation of tin into an alloyed epitaxial film. Additionally or alternatively, a group III dopant or a group V dopant may be utilized to precondition the chamber in a similar manner. In such an embodiment, preconditioning of the chamber with a group III dopant or a group V dopant may further reduce migration or out gassing of dopants within the deposited epitaxial film. In one example, preconditioning may begin about 1 second to about 60 seconds before deposition. It is contemplated that the preconditioning may constitute the introduction of precursor during that etching and/or annealing. That is, a single flow of tin precursor could be utilized to reduce tin migration during annealing/etching, and simultaneously precondition the processing chamber for the next deposition.

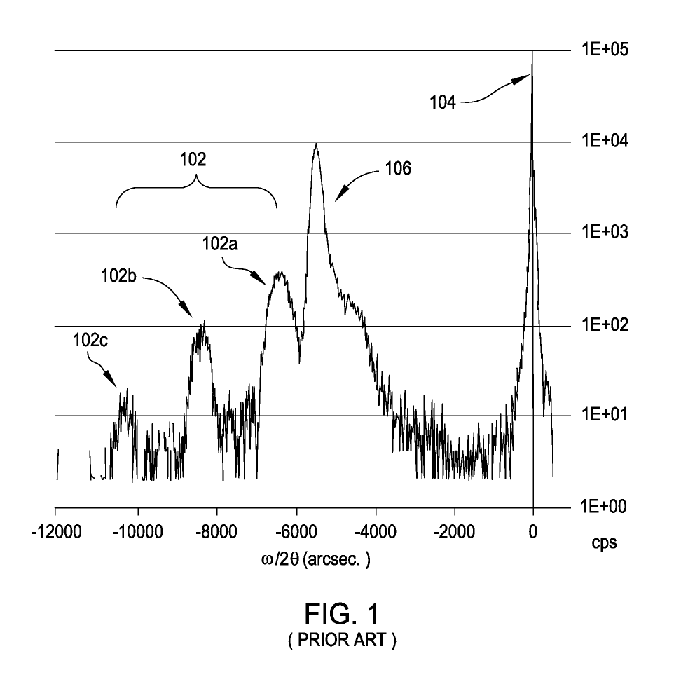

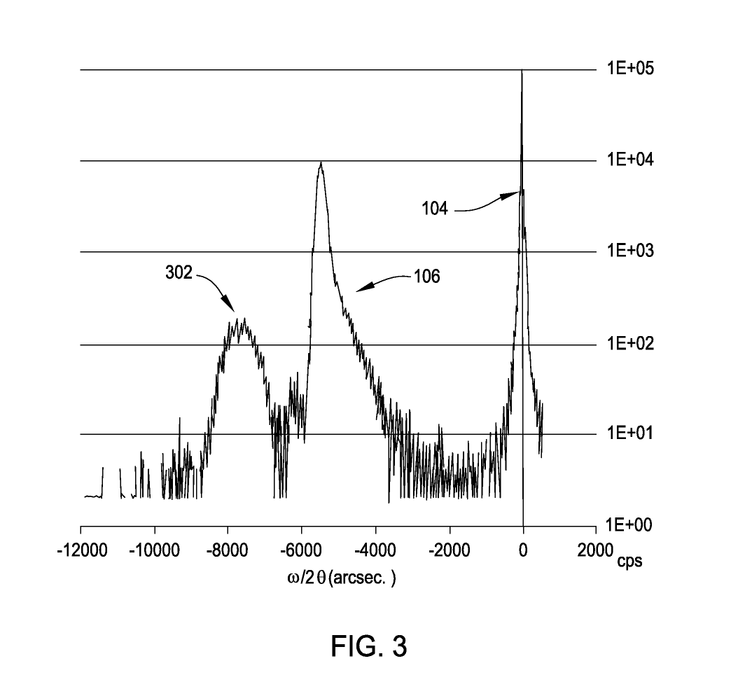

FIG. 3 illustrates X-ray diffraction data for a germanium-tin alloy epitaxial layer 302 formed on a silicon substrate 104 having a germanium buffer layer 106 thereon. The germanium-tin alloy epitaxial layer 302 was formed using a cyclical deposition/anneal process in which the anneal occurred in the presence of the tin precursor gas. The deposition/anneal process consisted of four cycles. As illustrated in FIG. 3, there is only a single peak corresponding to the germanium-tin alloy epitaxial layer 302. In contrast, the germanium-tin alloy epitaxial layer 102 of FIG. 1 includes three peaks, indicative of a non-uniform tin concentration. The single peak corresponding to the germanium-tin alloy epitaxial layer 302 in FIG. 3 indicates that the germanium-tin alloy epitaxial layer 302 has a uniform concentration of tin throughout. The uniform tin concentration of the germanium-tin alloy epitaxial layer 302 is facilitated by exposure of the germanium-tin alloy epitaxial layer 302 to the tin precursor gas during non-deposition intervals of processing (e.g., annealing).

In addition to facilitating dopant concentration uniformity, the flow of dopant gases, such as group III or group V dopant gas, during non-deposition phases of processing also reduces film surface roughness. In one example, a boron-doped germanium epitaxial film is deposited and then annealed. During deposition, a germanium hydride precursor gas and diborane are flowed into a chamber, and a boron-doped germanium epitaxial layer is formed. The boron-doped germanium epitaxial layer is deposited to a thickness of about 140 angstroms. At the conclusion of the deposition process, the boron-doped germanium epitaxial layer has a surface roughness of about 2.5 angstroms (arithmetic mean). After deposition, the boron-doped germanium epitaxial layer is annealed at 590° C. in a hydrogen atmosphere for 90 seconds. After annealing, the surface roughness of the boron-doped germanium epitaxial layer was 32.6 angstroms (arithmetic mean). The increased surface roughness is believed to be due to the migration of boron through the germanium epitaxial film because of the elevated annealing temperature.

In contrast, a similar layer deposited on a different substrate under the same conditions and having the same surface roughness was annealed in an atmosphere of hydrogen gas and diborane for 90 seconds at 590° C. The surface roughness of the layer after annealing in the presence of diborane was about 2.6 angstroms (arithmetic mean). Thus, by providing a dopant-containing gas to the process chamber atmosphere during non-deposition phases of processing, dopant migration can be reduced, film surface roughness can be improved, and overall film quality is maintained.

The anneal methods of the example described above may utilize thermal or laser anneals. Additionally, the annealing may take place in the same chamber as deposition, or in a different chamber. The migration of dopants is generally minimal during idle times, such as transportation of the substrate form one chamber to another. However, during processing, such as annealing, the migration of dopants is increased because of elevated processing temperatures. Therefore, it is desirable that a dopant-containing gas be provided to the process chamber during periods of elevated temperature in order to mitigate or reduce undesired dopant migration, as discussed above.

Benefits of the invention include the formation of epitaxial layers having uniform concentrations and improved surface roughness. The methods described herein are particularly beneficial for cyclical process which include a deposition/etch process or a deposition/anneal process. However, it is contemplated that embodiments described herein may be useful in any process in which it is desirable to reduce migration of elements within a film or to reduce out gassing of dopants from the film, including processes in which the deposition is not cyclical or repeated (e.g., only a single deposition operation is performed).

While the foregoing is directed to embodiments of the present invention, other and further embodiments of the invention may be devised without departing from the basic scope thereof, and the scope thereof is determined by the claims that follow.

We claim:

1. A method for forming an epitaxial material, comprising:
positioning a substrate within a chamber;
introducing a germanium precursor gas into the chamber;
introducing a tin precursor gas into the process chamber;
depositing a germanium-tin alloy epitaxial layer on the substrate;
halting the flow of the germanium precursor gas; and
performing at least one of an anneal process or an etching process on the germanium-tin alloy epitaxial layer, wherein the germanium-tin alloy epitaxial layer is exposed to the tin precursor gas during the anneal process or the etching process.

2. The method of claim 1, wherein the germanium precursor gas includes one or more of germane or digermane.

3. The method of claim 1, wherein the chamber is maintained at a pressure with a range of about 20 Torr to about 80 Torr.

4. The method of claim 1, wherein the tin precursor gas comprises a halide.

5. The method of claim 1, wherein the tin precursor gas comprises SnCl₄ or SnCl₂.

6. The method of claim 1, wherein the chamber is maintained at a temperature within a range of about 200 degrees Celsius to about 400 degrees Celsius while depositing the germanium-tin alloy epitaxial layer on the substrate.

7. The method of claim 1, wherein the tin precursor comprises an organometallic chloride having the formula RₓMCl_{y}, where R is a methyl of a t-butyl, x is 1 or 2, M is tin, and y is 2 or 3.

8. The method of claim 1, wherein the germanium-tin alloy epitaxial layer is deposited to a thickness between about 100 angstroms and about 800 angstroms.

9. The method of claim 8, wherein the germanium-tin alloy epitaxial layer comprises tin atoms in a germanium matrix, the tin having a concentration between about 1 percent and about 12 percent.

10. The method of claim 9, wherein the tin has a concentration of about seven percent to about 9 percent.

11. The method of claim 1, wherein the performing at least one of an anneal process or an etching process comprises performing an etching process with an etchant including Cl₂ or HCl.

12. The method of claim 1, wherein a flow rate of the tin precursor during the deposition of the germanium-tin alloy epitaxial layer on the substrate is substantially equal to a flow rate of the tin precursor during the annealing process or the etching process.

13. The method of claim 1, wherein the germanium-tin alloy epitaxial layer further comprises silicon.

14. The method of claim 1, wherein the germanium-tin alloy epitaxial layer is doped with a group III or group V dopant.

15. The method of claim 14, wherein the performing at least one of an anneal process or an etching process on the germanium-tin alloy epitaxial layer further comprises introducing a gas containing the group III or group V dopant.

16. The method of claim 1, wherein the group III or group V dopant comprises boron, arsenic, and phosphorus.

17. The method of claim 1, wherein the wherein the performing at least one of an anneal process or an etching process on the germanium-tin alloy epitaxial layer comprises laser annealing the germanium-tin alloy epitaxial layer.

18. The method of claim 1, further comprising preconditioning the chamber with a gas comprising the tin precursor.
